(19) United States
(12) Patent Application Publication
(10) Pub. No.: US 2026/0180432 A1
(43) Pub. Date: Jun. 25, 2026

(54) ABNORMALITY DETECTION APPARATUS

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Kiyoshi AIZAWA, Yokkaichi-shi, Mie (JP)

(73) Assignees: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(21) Appl. No.: 19/125,082

(22) PCT Filed: Nov. 2, 2022
(86) PCT No.: PCT/JP2022/041053

§ 371 Date: Apr. 28, 2025

(51) Int. Cl. H02M 1/32

(52) U.S. Cl. CPC H02M 1/32

(57) ABSTRACT

An abnormality detection apparatus: a power supply unit; and a first power line and a second power line that are provided between the power supply unit and a pyrotechnic interrupter. The abnormality detection apparatus includes: a first switch provided on the first power line; a second switch provided on the second power line; a first resistor unit; a second resistor unit; and a detection unit. The first resistor unit is electrically connected to a first portion between the power supply unit and the first switch and a second portion between the second switch and the pyrotechnic interrupter. The second resistor unit is electrically connected to the second portion and a third portion between the second switch and the power supply unit. The detection unit detects a voltage status of the second portion when at least either one of the first switch or the second switch is in an OFF state.

### CROSS-REFERENCE TO RELATED APPLICATIONS

This application is the U.S. national stage of PCT/JP2022/041053 filed on Nov. 2, 2022, the contents of which is incorporated herein.

### TECHNICAL FIELD

The present disclosure relates to an abnormality detection apparatus.

### BACKGROUND

JPH6-72281A discloses a technique for detecting a resistance value variation caused by a connection failure or deterioration of a squib in an igniter in an airbag by causing a test current to flow through the squib.

However, in order to ascertain whether the airbag can work normally it is preferable to also check whether, not only the squib, but also a switch for causing an ignition current to flow works normally whether a path from a power supply to the squib is not disconnected, and whether the power supply voltage is normal. The same applies to an operation of an initiator in a pyro-fuse that disconnects a power line.

The present disclosure has been accomplished based on the circumstances described above, and it is an object of the present disclosure to provide an abnormality detection apparatus that can detect an abnormality in a path from a power supply unit to a power supply target.

### SUMMARY

An abnormality detection apparatus according to the present disclosure is used in a supply system including a power supply unit that supplies power, a first power line provided between a high-potential side terminal of the power supply unit and a power supply target, and a second power line provided between a low-potential side terminal of the power supply unit and the power supply target, and the abnormality detection apparatus includes: a first switch provided on the first power line; a second switch provided on the second power line; a first resistor unit and a second resistor unit that form a current conduction path; and a detection unit that detects a voltage status, wherein, when the first switch is switched to an ON state, a current conduction via the first switch is allowed, and when the first switch is switched to an OFF state, the current conduction via the first switch is interrupted, when the second switch is switched to an ON state, a current conduction via the second switch is allowed, and when the second switch is switched to an OFF state, the current conduction via the second switch is interrupted, one end of the first resistor unit is electrically connected to a first portion on the first power line between the power supply unit and the first switch, and another end of the first resistor unit is electrically connected to a second portion on the second power line between the second switch and the power supply target, one end of the second resistor unit is electrically connected to the second portion, and another end of the second resistor unit is electrically connected to a third portion on the second power line between the second switch and the power supply unit, and the detection unit detects the voltage status of the second portion when at least either one of the first switch or the second switch is controlled to be in an OFF state.

### Advantageous Effects

According to the present disclosure, it is possible to detect an abnormality in a path from a power supply unit to a power supply target.

### BRIEF DESCRIPTION OF DRAWINGS

FIG. 1 is a circuit diagram showing an example of an abnormality detection apparatus according to Embodiment 1.

FIG. 2 is a schematic diagram showing a configuration of a pyrotechnic interrupter.

FIG. 3 is a flowchart illustrating an example of a determination operation performed by a detection unit included in the abnormality detection apparatus according to Embodiment 1.

FIG. 4 is a circuit diagram showing an example of an abnormality detection apparatus according to Embodiment 2.

FIG. 5 is a flowchart illustrating an example of a determination operation performed by a detection unit included in the abnormality detection apparatus according to Embodiment 2.

### DETAILED DESCRIPTION OF PREFERRED EMBODIMENTS

First, aspects of an embodiment according to the present disclosure will be listed and described.

In a first aspect, an abnormality detection apparatus according to the present disclosure is used in a supply system including a power supply unit that supplies power, a first power line provided between a high-potential side terminal of the power supply unit and a power supply target, and a second power line provided between a low-potential side terminal of the power supply unit and the power supply target. The abnormality detection apparatus according to the present disclosure includes: a first switch provided on the first power line; a second switch provided on the second power line; a first resistor unit and a second resistor unit that form a current conduction path; and a detection unit that detects a voltage status. When the first switch is switched to an ON state, a current conduction via the first switch is allowed, and when the first switch is switched to an OFF state, the current conduction via the first switch is interrupted. When the second switch is switched to an ON state, a current conduction via the second switch is allowed, and when the second switch is switched to an OFF state, the current conduction via the second switch is interrupted. One end of the first resistor unit is electrically connected to a first portion on the first power line between the power supply unit and the first switch, and another end of the first resistor unit is electrically connected to a second portion on the second power line between the second switch and the power supply target. One end of the second resistor unit is electrically connected to the second portion, and another end of the second resistor unit is electrically connected to a third portion on the second power line between the second switch and the power supply unit. The detection unit detects the voltage status of the second portion when at least either one of the first switch or the second switch is controlled to be in an OFF state.

With the abnormality detection apparatus according to the first aspect, it is possible to perform an operation in which the detection unit detects the voltage status of the second portion while power is not supplied to the power supply target from the power supply unit, and then the detection unit determines an abnormality in the supply system based on the detected voltage status.

In a second aspect, in the abnormality detection apparatus according to the first aspect, the power supply target may include a pyrotechnic interrupter provided on a predetermined conductive path. The pyrotechnic interrupter may include a conductor that causes a short-circuit between a first conductive path and a second conductive path included in the predetermined conductive path, and may cause an explosion to disconnect the conductor when a predetermined current flows between the first power line and the second power line.

In the abnormality detection apparatus according to the second aspect, the pyrotechnic interrupter disconnects the predetermined conductive path upon being activated. For this reason, by detecting the voltage of the second portion when at least either one of the first switch or the second switch is switched to an OFF state to prevent the pyrotechnic interrupter from being activated, the abnormality in the supply system can be determined.

In a third aspect, in the abnormality detection apparatus according to the first or the second aspect, the detection unit may determine whether the second portion has a voltage within an abnormal range when an OFF instruction is provided to the first switch and the second switch. The abnormal range may include at least either one of a voltage range that is less than or equal to a first threshold value that is less than a first normal voltage that is the voltage of the second portion when the first switch and the second switch are normally switched to an OFF state or a voltage range that is greater than or equal to a second threshold value that is greater than the first normal voltage.

In the abnormality detection apparatus according to the third aspect, the voltage of the second portion when the first switch and the second switch are normally switched to an ON state is equal to a value obtained by dividing an output voltage at the high-potential side terminal of the power supply unit by a voltage of the first resistor unit and a voltage of the second resistor unit. By comparing the first threshold value and the second threshold value that are based on this value as a reference with the actual voltage value of the second portion, it is possible to detect a drop or an increase in the power supply voltage, a disconnection on the first power line and the second power line, and a short-circuit failure in the first switch and the second switch.

In a fourth aspect, in the abnormality detection apparatus according to the first or the second aspect, the detection unit may determine whether the second portion has a voltage within an abnormal range when an ON instruction is provided to the first switch, and an OFF instruction is provided to the second switch. The abnormal range may include at least either one of a voltage range that is less than or equal to a third threshold value that is less than a second normal voltage or a voltage range that is greater than or equal to a fourth threshold value that is greater than the second normal voltage. The second normal voltage may be the voltage of the second portion when the first switch is normally switched to an ON state, and the second switch is normally switched to an OFF state.

In the abnormality detection apparatus according to the fourth aspect, when the first switch is normally switched to an ON state, the second switch is normally switched to an OFF state, and the power supply target has a normal resistance value, the voltage of the second portion has a value that is equal to a value obtained by dividing the output voltage at the high-potential side terminal of the power supply unit by a voltage of the second resistor unit and a voltage of a combined resistor in which the power supply target and the first resistor unit are connected in parallel. By comparing the third threshold value and the fourth threshold value that are based on this value as a reference with the actual voltage value of the second portion, it is possible to detect an open-circuit fault in the first switch, a connection failure in the power supply target, and a change in the resistance value of the power supply target.

In a fifth aspect, in the abnormality detection apparatus according to the first or the second aspect, the detection unit may determine whether the second portion has a voltage within an abnormal range when an OFF instruction is provided to the first switch, and an ON instruction is provided to the second switch. The abnormal range may include a voltage range that is greater than or equal to a fifth threshold value that is greater than a third normal voltage that is the voltage of the second portion when the first switch is normally switched to an OFF state and the second switch is normally switched to an ON state.

In the abnormality detection apparatus according to clause [5] described above, when the first switch is normally switched to an OFF state, and the second switch is normally switched to an ON state, the voltage of the second portion has a value that is equal to the voltage at the low-potential side terminal of the power supply unit. By comparing the fifth threshold value that is based on this value as a reference with the actual voltage value of the second portion, it is possible to detect an open-circuit fault in the second switch.

In a sixth aspect, the abnormality detection apparatus according to the first or the second aspect may include a series-connection portion in which a third switch and a third resistor unit are connected in series. One end of the series-connection portion may be electrically connected to the third portion, and another end of the series-connection portion may be electrically connected to the second portion.

The abnormality detection apparatus according to the sixth aspect further includes the series-connection portion in which a third switch and a third resistor unit are connected in series. With this configuration, the abnormality in the supply system can be more precisely determined.

In a seventh aspect, in the abnormality detection apparatus according to the sixth aspect, the detection unit may determine whether the second portion has a voltage within an abnormal range when an OFF instruction is provided to the first switch, the second switch, and the third switch. The abnormal range may include at least either one of a voltage range that is less than or equal to a first threshold value that is less than a first normal voltage or a voltage range that is greater than or equal to a second threshold value that is greater than the first normal voltage. The first normal voltage may be the voltage of the second portion when the first switch, the second switch, and the third switch are normally switched to an OFF state.

In the abnormality detection apparatus according to the seventh aspect, when the first switch, the second switch, and the third switch are normally switched to an OFF state, the voltage of the second portion has a value that is equal to a value obtained by dividing the output voltage at the high-potential side terminal of the power supply unit by a voltage of the first resistor unit and a voltage of the second resistor unit. By comparing the first threshold value and the second threshold value that are based on this value as a reference with the actual voltage value of the second portion, it is possible to detect a drop or an increase in the power supply voltage, a disconnection on the first power line and the second power line, and a short-circuit failure in the first switch and the second switch.

In an eighth aspect, in the abnormality detection apparatus according to the sixth aspect, the detection unit may determine whether the second portion has a voltage within an abnormal range when an ON instruction is provided to the first switch and the third switch, and an OFF instruction is provided to the second switch. The abnormal range may include at least either one of a voltage range that is less than or equal to a third threshold value that is less than a second normal voltage or a voltage range that is greater than or equal to a fourth threshold value that is greater than the second normal voltage. The second normal voltage may be the voltage of the second portion when the first switch and the third switch are normally switched to an ON state and the second switch is normally switched to an OFF state.

In the abnormality detection apparatus according to the eighth aspect, when the first switch and the third switch are normally switched to an ON state, the second switch is normally switched to an OFF state, and the power supply target has a normal resistance value, the voltage of the second portion has a value that is equal to a value obtained by dividing the output voltage at the high-potential side terminal of the power supply unit by a voltage of a combined resistor in which the power supply target and the first resistor unit are connected in parallel and a voltage of a combined resistor in which the second resistor unit and the third resistor unit are connected in parallel. By comparing the third threshold value and the fourth threshold value that are based on this value as a reference with the actual voltage value of the second portion, it is possible to detect an open-circuit fault in the first switch, a connection failure in the power supply target, and a change in the resistance value of the power supply target.

In a ninth aspect, in the abnormality detection apparatus according to the sixth aspect, the detection unit may determine whether the second portion has a voltage within an abnormal range when an OFF instruction is provided to the first switch and the third switch, and an ON instruction is provided to the second switch. The abnormal range may include a voltage range that is greater than or equal to a fifth threshold value that is greater than a third normal voltage that is the voltage of the second portion when the first switch and the third switch are normally switched to an OFF state, and the second switch is normally switched to an ON state.

In the abnormality detection apparatus according to the ninth aspect, when the first switch and the third switch are normally switched to an OFF state and the second switch is normally switched to an ON state, the voltage of the second portion has a value that is equal to the voltage at the low-potential side terminal of the power supply unit. By comparing the fifth threshold value that is based on this value as a reference with the actual voltage value of the second portion, it is possible to detect an open-circuit fault in the second switch.

In a tenth aspect, in the abnormality detection apparatus according to the sixth aspect, a value obtained by dividing a voltage at the high-potential side terminal of the power supply unit by a voltage of the first resistor unit and a voltage of the second resistor unit may be equal to a value obtained by dividing the voltage at the high-potential side terminal of the power supply unit by a voltage of the third resistor unit and a voltage of the power supply target.

In the abnormality detection apparatus according to the tenth aspect, the first normal voltage that is used as a reference for the first threshold value and the second threshold value can have the same value as the second normal voltage that is used as a reference for the third threshold value and the fourth threshold value. Accordingly, in the case where the detection unit is configured using a comparator, the number of comparators that need to be provided can be reduced.

### Embodiment 1

### Overview of Supply System

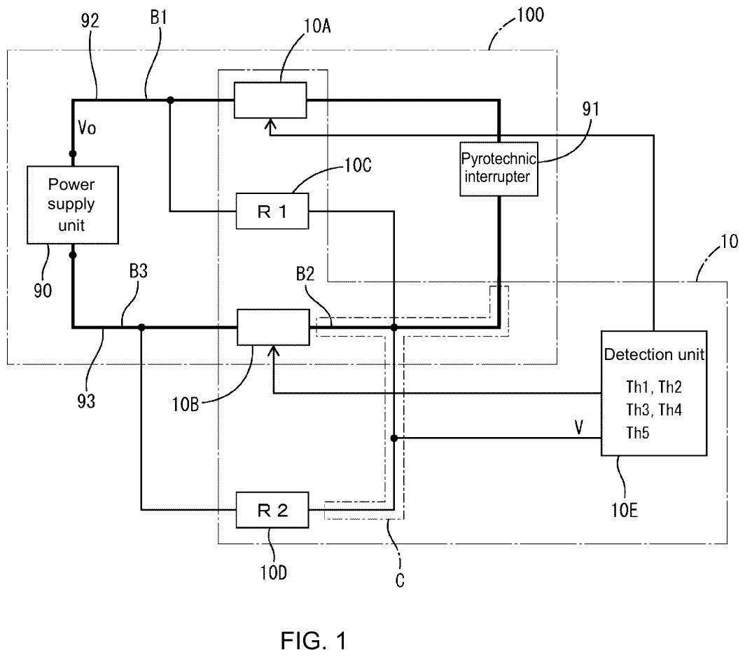

A supply system 100 shown in FIG. 1 is a system mounted in a vehicle. The supply system 100 includes a power supply unit 90, a pyrotechnic interrupter 91 that is a power supply target, and an abnormality detection apparatus 10. As the power supply unit 90, for example, a lead acid battery a lithium ion battery or the like is used. The power supply unit 90 includes a high-potential side terminal and a low-potential side terminal. The power supply unit 90 has an output voltage Vo (a potential difference between the high-potential side terminal and the low-potential side terminal). The voltage at the low-potential side terminal of the power supply unit 90 is reference potential, and is kept at, for example, a ground potential of 0 V. One end of a first power line 92 is electrically connected to the high-potential side terminal of the power supply unit 90. One end of a second power line 93 is electrically connected to the low-potential side terminal of the power supply unit 90. The first power line 92 and the second power line 93 are power transmission paths.

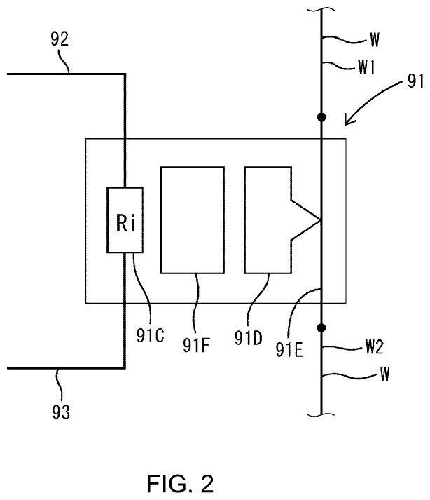

As the pyrotechnic interrupter 91, for example, a pyro-fuse (PYROFUSE (registered trademark)) is used. The pyrotechnic interrupter 91 is provided between the first power line 92 and the second power line 93. As shown in FIG. 2, the pyrotechnic interrupter 91 includes an initiator 91C, a pyrotechnic element 91F, a displaceable portion 91D, and a conductor 91E.

The initiator 91C is electrically connected to the other end of the first power line 92 and the other end of the second power line 93. The first power line 92 and the second power line 93 are provided between the power supply unit 90 and the initiator 91C. The initiator 91C is configured to generate heat when a first switch 10A and a second switch 10B, which will be described later, are switched to an ON state from an OFF state, and a predetermined current flows between the first power line 92 and the second power line 93. The initiator 91C has a resistance value Ri. The pyrotechnic element 91F is provided adjacent to the initiator 91C. Upon receiving heat generated by the initiator 91C, the pyrotechnic element 91F explodes to generate an explosive force. That is, the initiator 91C performs an explosion operation of igniting the pyrotechnic element 91F in response to power being supplied from the power supply unit 90. When the pyrotechnic element 91F is ignited, the pyrotechnic element 91F generates an explosive force. The displaceable portion 91D is provided adjacent to the pyrotechnic element 91F. The displaceable portion 91D rapidly displaces upon receiving the explosive force generated by the exploded pyrotechnic element 91F.

The conductor 91E is formed using, for example, a strip-shaped conductive metal. The conductor 91E is electrically connected to a first conductive path W1 and a second conductive path W2 that are included in a predetermined conductive path W in such a manner that it can cause a short-circuit between the first conductive path W1 and the second conductive path W2. The conductor 91E is provided on the opposite side of the pyrotechnic element 91F across the displaceable portion 91D. The conductor 91E is physically disconnected in a very short time as a result of the displaceable portion 91D rapidly displacing upon receiving the explosive force generated by the explosion operation. With this configuration, when the conductor 91E is disconnected, the conductor 91E interrupts the predetermined conductive path W. Once the conductor 91E is disconnected, the conductor 91E is no longer connected again. That is, the pyrotechnic interrupter 91 is a fuse apparatus that disconnects the conductor 91E by displacement of the displaceable portion 91D in response to the explosion operation.

In the present disclosure, the expression “electrically connected” desirably refers to a configuration in which two connection targets are connected in a mutually conductive state (in which an electric current can flow) such that the two connection targets have an equal potential. However, the expression “electrically connected” is not limited to this configuration. For example, the expression “electrically connected” may refer to a configuration in which two connection targets are connected via an electric component that is provided between the connection targets such that the connection targets can be mutually electrically conductive. In the present disclosure, the term “short-circuit” means, out of the “electrically connected” configurations, the configuration in which two connection targets are connected in a mutually conductive state (in which an electric current can flow) such that the two connection targets have an equal potential.

As shown in FIG. 1, the abnormality detection apparatus 10 includes the first switch 10A, a second switch 10B, a first resistor unit 10C, a second resistor unit 10D, and a detection unit 10E. The first switch 10A is provided on the first power line 92. The second switch 10B is provided on the second power line 93. The first switch 10A and the second switch 10B have a switching function of switching between an ON state and an OFF state. When the first switch 10A and the second switch 10B are switched to an ON state, a current conduction via the first switch 10A and the second switch 10B is allowed. Then, each of the first power line 92 and the second power line 93 can thereby conduct an electric current between the power supply unit 90 and the pyrotechnic interrupter 91.

When the first switch 10A and the second switch 10B are switched to an OFF state, the current conduction via the first switch 10A and the second switch 10B is interrupted. Then, each of the first power line 92 and the second power line 93 thereby interrupts the conduction of the electric current between the power supply unit 90 and the pyrotechnic interrupter 91. As each of the first switch 10A and the second switch 10B, for example, a relay switch such as a semiconductor relay or a mechanical relay is used.

As each of the first resistor unit 10C and the second resistor unit 10D, an electric resistor that has two terminals is used. The first resistor unit 10C has a resistance value R1, and the second resistor unit 10D has a resistance value R2. One end of the first resistor unit 10C is electrically connected to a first portion B1 on the first power line 92 between the power supply unit 90 and the first switch 10A. Another end of the first resistor unit 10C is electrically connected to a second portion B2 on the second power line 93 between the second switch 10B and the pyrotechnic interrupter 91. The first resistor unit 10C functions as a current conduction path between the first portion B1 and the second portion B2. One end of the second resistor unit 10D is electrically connected to the second portion B2 on the second power line 93 between the second switch 10B and the pyrotechnic interrupter 91. Another end of the second resistor unit 10D is electrically connected to a third portion B3 on the second power line 93 between the second switch 10B and the power supply unit 90. The second resistor unit 10D functions as a current conduction path between the second portion B2 and the third portion B3. In order to suppress a dark current, the resistance value R1 and the resistance value R2 are preferably set to sufficiently large values.

The detection unit 10E is composed mainly of, for example, a microcomputer, and also includes a computation device such as a CPU (Central Processing Unit), a memory such as a ROM (Read Only Memory) or a RAM (Random Access Memory), an A/D converter, and the like. The detection unit 10E is electrically connected to the second portion B2 on the second power line 93 that is electrically connected to the other end of the second resistor unit 10D. The detection unit 10E is configured to receive an input of a voltage value V applied to the second portion B2 and detect a voltage status of the second portion B2.

In the ROM or the like of the detection unit 10E, a first threshold value Th1, a second threshold value Th2, a third threshold value Th3, a fourth threshold value Th4, and a fifth threshold value Th5 are stored. The detection unit 10E has a function of determining whether the second portion B2 has an abnormal voltage by comparing the voltage value V of the second portion B2 with the first threshold value Th1, the second threshold value Th2, the third threshold value Th3, the fourth threshold value Th4, and the fifth threshold value Th5.

The first threshold value Th1 and the second threshold value Th2 are based on a first normal voltage Vd1 that is the voltage of the second portion B2 when the first switch 10A and the second switch 10B are normally switched to an OFF state. Here, the first normal voltage Vd1 has a value obtained by dividing the output voltage Vo of the power supply unit 90 by a voltage of the first resistor unit 10C (resistance value R1) and a voltage of the second resistor unit 10D (resistance value R2), and can be expressed by Equation 1 given below. For example, the output voltage Vo of the power supply unit 90 is a potential difference between the high-potential side terminal and the low-potential side terminal of the power supply unit 90 when the power supply unit 90 is in a fully charged state. Also, the first normal voltage Vd1 is a voltage value obtained when the power supply unit 90 is in a fully charged state.

$$[ Math . 1 ]$$

$$Vd 1 = \frac{R 2}{R 1 + R 2} Vo \qquad Equation 1$$

The first threshold value Th1 is less than the first normal voltage Vd1 by a predetermined value. The second threshold value Th2 is greater than the first normal voltage Vd1 by a predetermined value. The values of the first threshold value Th1 and the second threshold value Th2 can be changed to desired values according to the required specifications.

The third threshold value Th3 and the fourth threshold value Th4 are based on a second normal voltage Vd2 that is the voltage of the second portion B2 when the first switch 10A is normally switched to an ON state and the second switch 10B is normally switched to an OFF state. The second normal voltage Vd2 is a voltage value obtained when the power supply unit 90 is in a fully charged state. Here, the second normal voltage Vd2 has a value obtained by dividing using a voltage of the first resistor unit 10C (resistance value R1), a voltage of the initiator 91C (resistance value Ri), the first resistor unit 10C and the initiator 91C being connected in parallel, and a voltage of the second resistor unit 10D (resistance value R2), and can be expressed by Equation 2 given below.

$$[ Math . 2 ]$$

$$Vd 2 = \frac{R 2}{\frac{R 1 \times Ri}{R 1 + Ri} + R 2} Vo \qquad Equation 2$$

The third threshold value Th3 is less than the second normal voltage Vd2 by a predetermined value. The fourth threshold value Th4 is greater than the second normal voltage Vd2 by a predetermined value. The values of the third threshold value Th3 and the fourth threshold value Th4 can be changed to desired values according to the required specifications.

The fifth threshold value Th5 is based on a third normal voltage Vd3 that is the voltage of the second portion B2 when the first switch 10A is normally switched to an OFF state and the second switch 10B is normally switched to an ON state. The third normal voltage Vd3 has the same voltage (the ground potential) as that at the low-potential side terminal of the power supply unit 90. The fifth threshold value Th5 is greater than the third normal voltage Vd3 (the ground potential) by a predetermined value. The value of the fifth threshold value Th5 can be changed to a desired value according to the required specifications.

Furthermore, the detection unit 10E may perform control to independently switch the first switch 10A and the second switch 10B between an OFF state and an ON state. Specifically the detection unit 10E may perform a first switch control, a second switch control, and a third switch control. The first switch control, the second switch control, and the third switch control are performed after an ignition switch provided in the vehicle has been switched from an OFF state to an ON state. The first switch control refers to a control that provides an OFF instruction to the first switch 10A and the second switch 10B and maintains the first switch 10A and the second switch 10B in an OFF state. The second switch control refers to a control that provides an ON instruction to the first switch 10A, maintains the first switch 10A in an ON state, provides an OFF instruction to the second switch 10B, and maintains the second switch 10B in an OFF state. The third switch control refers to a control that provides an OFF instruction to the first switch 10A, maintains the first switch 10A in an OFF state, provides an ON instruction to the second switch 10B, and maintains the second switch 10B in an ON state.

### Example of Operation of Abnormality Detection Apparatus

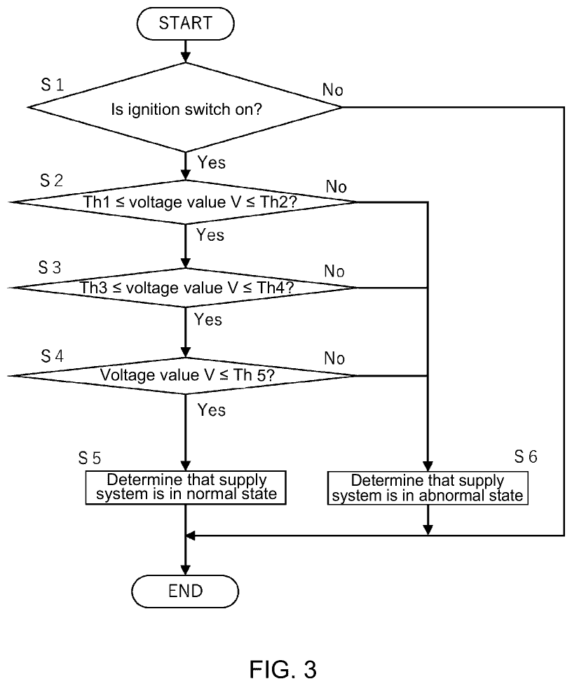

Next, an example of an operation performed by the abnormality detection apparatus 10 will be described. In the vehicle on which the supply system 100 is mounted, when the ignition switch is in an OFF state, the first switch 10A and the second switch 10B are switched to an OFF state. In this case, No is determined in step S1 shown in FIG. 3, and the processing shown in FIG. 3 ends. In step S1, when the ignition switch is switched from the OFF state to an ON state (Yes in step S1), the processing transitions to step S2. In step S2, the detection unit 10E performs the first switch control that provides an OFF instruction to the first switch 10A and the second switch 10B and maintains the first switch 10A and the second switch 10B in an OFF state.

The detection unit 10E acquires the voltage value V of the second portion B2. In step S2, the detection unit 10E compares, in terms of magnitude, the voltage value V with the first threshold value Th1 and the second threshold value Th2, and determines whether the second portion B2 has a voltage within an abnormal range.

When the voltage value V is less than the first threshold value Th1, it is estimated that the voltage of the second portion B2 has dropped due to a disconnection on the first power line 92 between the first resistor unit 10C and the power supply unit 90 or a short-circuit failure in the second switch 10B. When the voltage value V is greater than the second threshold value Th2, it is estimated that the voltage of the second portion B2 has increased due to a disconnection on the second power line 93 between the second portion B2 and the power supply unit 90 or a short-circuit failure has occurred in the first switch 10A. Accordingly when the detection unit 10E determines that the voltage value V is less than the first threshold value Th1, or the voltage value V is greater than the second threshold value Th2 (No in step S2), the processing transitions to step S6. When the processing transitions to step S6, the detection unit 10E determines that the supply system 100 is in an abnormal state, and the processing shown in FIG. 3 ends. The abnormal range of the voltage of the second portion B2 in step S2 includes at least either one of a voltage range that is less than or equal to the first threshold value Th1 that is less than the first normal voltage Vd1 or a voltage range that is greater than or equal to the second threshold value Th2 that is greater than the first normal voltage Vd1. The first normal voltage Vd1 is the voltage of the second portion B2 when the first switch 10A and the second switch 10B are normally switched to an OFF state. When the voltage value V is less than or equal to the second threshold value Th2 and greater than or equal to the first threshold value Th1 (Yes in step S2), the processing transitions to step S3.

When the processing transitions to step S3, the detection unit 10E performs the second switch control that provides an ON instruction to the first switch 10A, maintains the first switch 10A in an ON state, provides an OFF instruction to the second switch 10B, and maintains the second switch 10B in an OFF state. Then, the detection unit 10E determines whether the second portion B2 has a voltage within an abnormal range. When the processing transitions to step S3, the detection unit 10E compares, in terms of magnitude, the voltage value V of the second portion B2 with the third threshold value Th3 and the fourth threshold value Th4.

When the voltage value V is less than the third threshold value Th3, it is estimated that the voltage of the second portion B2 has dropped due to an open-circuit fault in the first switch 10A or an open-circuit fault caused by a connection failure between the initiator 91C and the first power line 92. When the voltage value V is greater than the fourth threshold value Th4, it is estimated that the voltage of the second portion B2 has increased due to a change in the resistance value Ri caused by an alteration of the initiator 91C or a short circuit in the initiator 91C caused by a connection failure between the initiator 91C and the first power line 92. Accordingly when the detection unit 10E determines that the voltage value V is less than the third threshold value Th3, or the voltage value V is greater than the fourth threshold value Th4 (No in step S3), the processing transitions to step S6. When the processing transitions to step S6, the detection unit 10E determines that the supply system 100 is in an abnormal state, and the processing shown in FIG. 3 ends. The abnormal range of the voltage of the second portion B2 in step S3 includes at least either one of a voltage range that is less than or equal to the third threshold value Th3 that is less than the second normal voltage Vd2 or a voltage range that is greater than or equal to the fourth threshold value Th4 that is greater than the second normal voltage Vd2. The second normal voltage Vd2 is the voltage of the second portion B2 when the first switch 10A is normally switched to an ON state and the second switch 10B is normally switched to an OFF state. When the voltage value V is less than or equal to the fourth threshold value Th4 and is greater than or equal to the third threshold value Th3 (Yes in step S3), the processing transitions to step S4.

When the processing transitions to step S4, the detection unit 10E performs the third switch control that provides an OFF instruction to the first switch 10A, maintains the first switch 10A in an OFF state, provides an ON instruction to the second switch 10B, and maintains the second switch 10B in an ON state. Then, the detection unit 10E determines whether the second portion B2 has a voltage within an abnormal range. When the processing transitions to step S4, the detection unit 10E compares, in terms of magnitude, the voltage value V of the second portion B2 with the fifth threshold value Th5.

When the voltage value V is greater than the fifth threshold value Th5, it is estimated that the voltage of the second portion B2 has increased due to an open-circuit fault in the second switch 10B. Accordingly, when the detection unit 10E determines that the voltage value V is greater than the fifth threshold value Th5 (No in step S4), the processing transitions to step S6, where the detection unit 10E determines that the supply system 100 is in an abnormal state, and the processing shown in FIG. 3 ends. When the voltage value V is less than or equal to the fifth threshold value Th5 (Yes in step S4), the processing transitions to step S5. When the processing transitions to step S5, the detection unit 10E determines that the supply system 100 is in a normal state, and the processing shown in FIG. 3 ends. The abnormal range of the voltage of the second portion B2 in step S4 includes a voltage range that is greater than or equal to the fifth threshold value Th5 that is greater than the third normal voltage Vd3 that is the voltage of the second portion B2 when the first switch 10A is normally switched to an OFF state and the second switch 10B is normally switched to an ON state. As described above, the detection unit 10E detects the voltage status of the second portion B2 when at least either one of the first switch 10A or the second switch 10B is controlled to be in an OFF state.

Next, advantageous effects of the configuration of the present disclosure are shown below.

An abnormality detection apparatus 10 is used in a supply system 100 including: a power supply unit 90 that supplies power; a first power line 92 provided between a high-potential side terminal of the power supply unit 90 and a pyrotechnic interrupter 91; and a second power line 93 provided between a low-potential side terminal of the power supply unit 90 and the pyrotechnic interrupter 91. The abnormality detection apparatus 10 includes: a first switch 10A provided on the first power line 92; a second switch 10B provided on the second power line 93; a first resistor unit 10C and a second resistor unit 10D that form a current conduction path; and a detection unit 10E that detects a voltage status. When the first switch 10A is switched to an ON state, a current conduction via the first switch 10A is allowed. When the first switch 10A is switched to an OFF state, the current conduction via the first switch 10A is interrupted. When the second switch 10B is switched to an ON state, a current conduction via the second switch 10B is allowed. When the second switch 10B is switched to an OFF state, the current conduction via the second switch 10B is interrupted. One end of the first resistor unit 10C is electrically connected to a first portion B1 on the first power line 92 between the power supply unit 90 and the first switch 10A. Another end of the first resistor unit 10C is electrically connected to a second portion B2 on the second power line 93 between the second switch 10B and the pyrotechnic interrupter 91. One end of the second resistor unit 10D is electrically connected to the second portion B2, and another end of the second resistor unit 10D is electrically connected to a third portion B3 on the second power line 93 between the second switch 10B and the power supply unit 90. The detection unit 10E detects the voltage status of the second portion B2 when at least either one of the first switch 10A or the second switch 10B is controlled to be in an OFF state.

With this configuration, it is possible to perform an operation in which, in a state in which power is not supplied to the pyrotechnic interrupter 91 from the power supply unit 90, the detection unit 10E detects the voltage status of the second portion B2, and determines, based on the detected voltage status, an abnormality in the supply system 100.

In the abnormality detection apparatus 10, the pyrotechnic interrupter 91 is provided on a predetermined conductive path W. The pyrotechnic interrupter 91 includes a conductor 91E that causes a short-circuit between a first conductive path W1 and a second conductive path W2 included in the predetermined conductive path W. When a predetermined current flows between the first power line 92 and the second power line 93, the pyrotechnic interrupter 91 causes an explosion to disconnect the conductor 91E. With this configuration, the pyrotechnic interrupter 91 disconnects the predetermined conductive path W upon being activated. For this reason, by detecting the voltage of the second portion B2 when at least either one of the first switch 10A or the second switch 10B is switched to an OFF state to prevent the pyrotechnic interrupter from being activated, it is possible to determine an abnormality in the supply system 100.

In the abnormality detection apparatus 10, when an OFF instruction is provided to the first switch 10A and the second switch 10B, the detection unit 10E determines whether the second portion B2 has a voltage within an abnormal range. The abnormal range includes at least either one of a voltage range that is less than or equal to the first threshold value Th1 that is less than a first normal voltage Vd1 or a voltage range that is greater than or equal to the second threshold value Th2 that is greater than the first normal voltage Vd1. The first normal voltage Vd1 is the voltage of the second portion B2 when the first switch 10A and the second switch 10B are normally switched to an OFF state. With this configuration, the voltage of the second portion B2 when the first switch 10A and the second switch 10B are normally switched to an ON state is the first normal voltage Vd1 obtained by dividing an output voltage Vo at the high-potential side terminal of the power supply unit 90 by a voltage of the first resistor unit 10C and a voltage of the second resistor unit 10D. By comparing the first threshold value Th1 and the second threshold value Th2 that are based on this value as a reference with the actual voltage value V of the second portion B2, it is possible to detect a drop or increase in the power supply voltage, a disconnection on the first power line 92 and the second power line 93, and a short-circuit failure in the first switch 10A and the second switch 10B.

In the abnormality detection apparatus 10, when an ON instruction is provided to the first switch 10A and an OFF instruction is provided to the second switch 10B, the detection unit 10E determines whether the second portion B2 has a voltage within an abnormal range. The abnormal range includes at least either one of a voltage range that is less than or equal to a third threshold value Th3 that is less than a second normal voltage Vd2 or a voltage range that is greater than or equal to a fourth threshold value Th4 that is greater than the second normal voltage Vd2. The second normal voltage Vd2 is the voltage of the second portion B2 when the first switch 10A is normally switched to an ON state and the second switch 10B is normally switched to an OFF state. With this configuration, when the first switch 10A is normally switched to an ON state, the second switch 10B is normally switched to an OFF state, and the initiator 91C of the pyrotechnic interrupter 91 has a normal resistance value Ri, the voltage of the second portion B2 has a value obtained by dividing the output voltage Vo at the high-potential side terminal of the power supply unit 90 by a voltage of the second resistor unit 10D and a voltage of a combined resistor in which the initiator 91C and the first resistor unit 10C are connected in parallel. By comparing the third threshold value Th3 and the fourth threshold value Th4 that are based on this value as a reference with the actual voltage value V of the second portion B2, it is possible to detect an open-circuit fault in the first switch 10A, a connection failure in the pyrotechnic interrupter 91, and a change in the resistance value Ri of the initiator 91C of the pyrotechnic interrupter 91.

In the abnormality detection apparatus 10, when an OFF instruction is provided to the first switch 10A and an ON instruction is provided to the second switch 10B, the detection unit 10E determines whether the second portion B2 has a voltage within an abnormal range. The abnormal range includes a voltage range that is greater than or equal to a fifth threshold value Th5 that is greater than a third normal voltage Vd3 that is the voltage of the second portion B2 when the first switch 10A is normally switched to an OFF state and the second switch 10B is normally switched to an ON state. With this configuration, when the first switch 10A is normally switched to an OFF state and the second switch 10B is normally switched to an ON state, the voltage of the second portion B2 has a value that is equal to the voltage at the low-potential side terminal of the power supply unit 90. By comparing the fifth threshold value Th5 that is based on this value as a reference with the actual voltage value V of the second portion B2, it is possible to detect an open-circuit fault in the second switch 10B.

### Embodiment 2

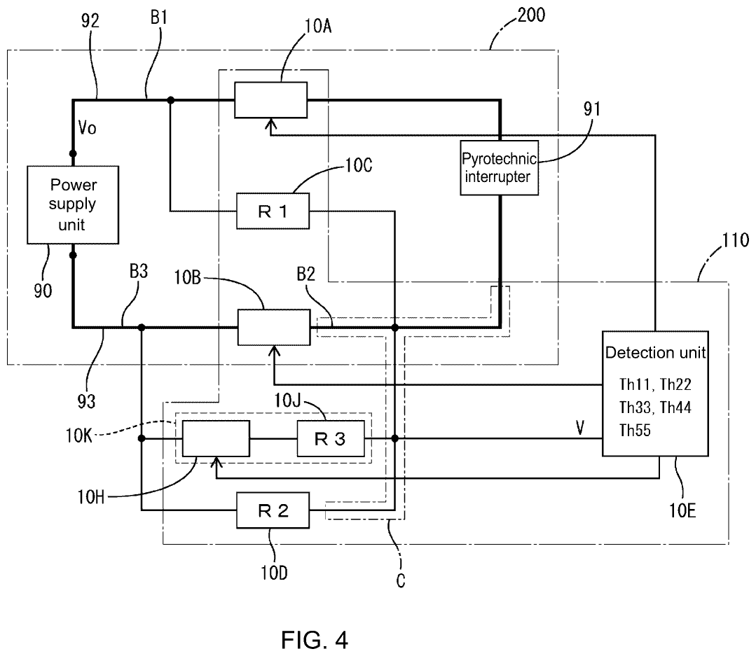

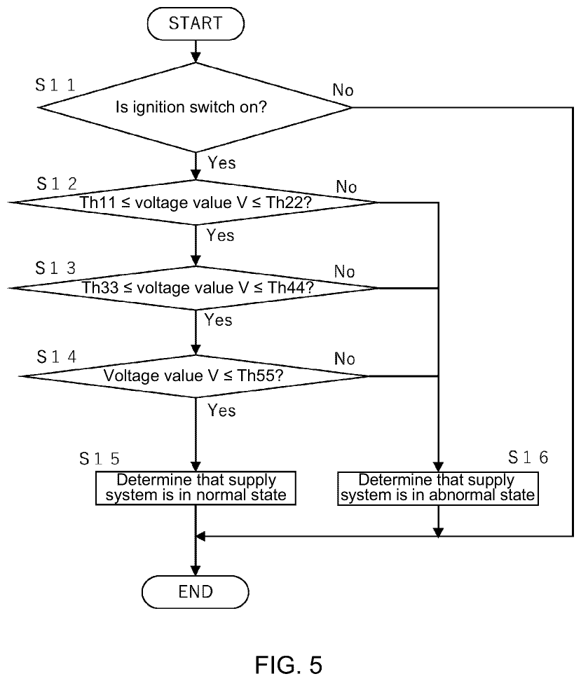

Next, an abnormality detection apparatus 110 according to Embodiment 2 will be described with reference to FIGS. 4 and 5. Embodiment 2 is different from Embodiment 1 in that the abnormality detection apparatus 110 includes a third switch 10H and a third resistor unit 10J, and the detection unit 10E performs a different operation and the like. The constituent elements that are the same as those of Embodiment 1 are given the same reference numerals, and a description of the actions and advantageous effects that are the same as those of Embodiment 1 is omitted.

As the third switch 10H, for example, a relay switch such as a semiconductor relay or a mechanical relay is used. As the third resistor unit 10J, an electric resistor that has two terminals is used. The third resistor unit 10J has a resistance value R3. The third switch 10H and the third resistor unit 10J are electrically connected in series to constitute a series-connection portion 10K. As shown in FIG. 4, one end of the series-connection portion 10K that is one end of the third switch 10H is electrically connected to the third portion B3. Another end of the series-connection portion 10K that is another end of the third resistor unit 10J is electrically connected to the second portion B2. The series-connection portion 10K, the second resistor unit 10D, and the second switch 10B are electrically connected in parallel.

In the ROM or the like of the detection unit 10E, a first threshold value Th11, a second threshold value Th22, a third threshold value Th33, a fourth threshold value Th44, and a fifth threshold value Th55 are stored. The detection unit 10E has a function of determining whether the second portion B2 has an abnormal voltage by comparing the voltage value V of the second portion B2 with the first threshold value Th11, the second threshold value Th22, the third threshold value Th33, the fourth threshold value Th44, and the fifth threshold value Th55.

The first threshold value Th11 and the second threshold value Th22 are based on a first normal voltage Vd1 that is the voltage of the second portion B2 when the first switch 10A, the second switch 10B, and the third switch 10H are normally switched to an OFF state. The first normal voltage Vd1 has a value obtained by dividing the output voltage Vo of the power supply unit 90 by a voltage of the first resistor unit 10C (resistance value R1) and a voltage of the second resistor unit 10D (resistance value R2), and can be expressed by Equation 1 shown in Embodiment 1.

The first threshold value Th11 is less than the first normal voltage Vd1 by a predetermined value. The second threshold value Th22 is greater than the first normal voltage Vd1 by a predetermined value. The values of the first threshold value Th11 and the second threshold value Th22 can be changed to desired values according to the required specifications.

The third threshold value Th33 and the fourth threshold value Th44 are based on a second normal voltage Vd2 that is the voltage of the second portion B2 when the first switch 10A and the third switch 10H are normally switched to an ON state and the second switch 10B is normally switched to an OFF state. Here, the second normal voltage Vd2 has a value obtained by dividing using a voltage of the first resistor unit 10C (resistance value R1), a voltage of the initiator 91C (resistance value Ri), the first resistor unit 10C and the initiator 91C being connected in parallel, and a voltage of the second resistor unit 10D (resistance value R2), and a voltage of the third resistor unit 10J (resistance value R3), the second resistor unit 10D and the third resistor unit 10J being connected in parallel, and can be expressed by Equation 3 given below.

$$[ Math . 3 ]$$

$$Vd 2 = \frac{\frac{R 2 \times R 3}{R 2 + R 3}}{\frac{R 1 \times Ri}{R 1 + Ri} + \frac{R 2 \times R 3}{R 2 + R 3}} Vo \qquad Equation 3$$

The third threshold value Th33 is less than the second normal voltage Vd2 by a predetermined value. The fourth threshold value Th44 is greater than the second normal voltage Vd2 by a predetermined value. The values of the third threshold value Th33 and the fourth threshold value Th44 can be changed to desired values according to the required specifications.

The fifth threshold value Th55 is based on a third normal voltage Vd3 that is the voltage of the second portion B2 when the first switch 10A and the third switch 10H are normally switched to an OFF state and the second switch 10B is normally switched to an ON state. The third normal voltage Vd3 has the same voltage (the ground potential) as that at the low-potential side terminal of the power supply unit 90. The fifth threshold value Th55 is greater than the third normal voltage Vd3 by a predetermined value. The value of the fifth threshold value Th55 can be changed to a desired value according to the required specifications.

The first switch control performed by the detection unit 10E is a control that maintains the first switch 10A, the second switch 10B, and the third switch 10H in an OFF state. The second switch control performed by the detection unit 10E is a control that maintains the first switch 10A and the third switch 10H in an ON state, and maintains the second switch 10B in an OFF state. The third switch control performed by the detection unit 10E is a control that maintains the first switch 10A and the third switch 10H in an OFF state, and maintains the second switch 10B in an ON state.

### Example of Operation of Abnormality Detection Apparatus

Next, an example of an operation performed by the abnormality detection apparatus 110 will be described. In the vehicle in which a supply system 200 is mounted, when the ignition switch is in an OFF state, the first switch 10A, the second switch 10B, and the third switch 10H are in an OFF state. For example, in step S11 shown in FIG. 5, when the ignition switch is switched from the OFF state to an ON state (Yes in step S1), the processing transitions to step S12. In step S12, the detection unit 10E performs the first switch control that maintains the first switch 10A, the second switch 10B, and the third switch 10H in the OFF state.

The detection unit 10E acquires the voltage value V of the second portion B2. In step S12, the detection unit 10E compares, in terms of magnitude, the voltage value V with the first threshold value Th11 and the second threshold value Th22, and determines whether the second portion B2 has a voltage within an abnormal range.

When the voltage value V is less than the first threshold value Th11, it is estimated, due to a disconnection on the first power line 92 between the first resistor unit 10C and the power supply unit 90 or a short-circuit failure in the second switch 10B, the voltage of the second portion B2 has dropped. When the voltage value V is greater than the second threshold value Th22, it is estimated that the voltage of the second portion B2 has increased due to a disconnection on the second power line 93 between the second portion B2 and the power supply unit 90 or a short-circuit failure in the first switch 10A. Accordingly, when the detection unit 10E determines that the voltage value V is less than the first threshold value Th11 or the voltage value V is greater than the second threshold value Th22 (No in step S12), the processing transitions to step S16. When the processing transitions to step S16, the detection unit 10E determines that the supply system 200 is in an abnormal state, and the processing shown in FIG. 5 ends. The abnormal range of the voltage of the second portion B2 in step S12 includes at least either one of a voltage range that is less than or equal to the first threshold value Th11 that is less than the first normal voltage Vd1 or a voltage range that is greater than or equal to the second threshold value Th22 that is greater than the first normal voltage Vd1. The first normal voltage Vd1 is the voltage of the second portion B2 when the first switch 10A, the second switch 10B, and the third switch 10H are normally switched to an OFF state. When the voltage value V is less than or equal to the second threshold value Th22 and greater than or equal to the first threshold value Th11 (Yes in step S12), the processing transitions to step S13.

When the processing transitions to step S13, the detection unit 10E performs the second switch control that maintains the first switch 10A and the third switch 10H in the ON state, and maintains the second switch 10B in the OFF state. Then, the detection unit 10E determines whether the second portion B2 has a voltage within an abnormal range. When the processing transitions to step S13, the detection unit 10E compares, in terms of magnitude, the voltage value V of the second portion B2 with the third threshold value Th33 and the fourth threshold value Th44.

When the voltage value V is less than the third threshold value Th33, it is estimated that the voltage of the second portion B2 has dropped due to an open-circuit fault in the first switch 10A, an increase in the resistance value Ri caused by an alteration of the initiator 91C, or an open-circuit fault caused by a connection failure between the initiator 91C and the first power line 92. When the voltage value V is greater than the fourth threshold value Th44, it is estimated that the voltage of the second portion B2 has increased due to a drop in the resistance value Ri caused by an alteration of the initiator 91C or a short circuit in the initiator 91C caused by a connection failure between the initiator 91C and the first power line 92. Accordingly, when the detection unit 10E determines that the voltage value V is less than the third threshold value Th33 or the voltage value V is greater than the fourth threshold value Th44 (No in step S13), the processing transitions to step S16. When the processing transitions to step S16, the detection unit 10E determines that the supply system 200 is in an abnormal state, and the processing shown in FIG. 5 ends. The abnormal range of the voltage of the second portion B2 in step S13 includes at least either one of a voltage range that is less than or equal to the third threshold value Th33 that is less than the second normal voltage Vd2 or a voltage range that is greater than or equal to the fourth threshold value Th44 that is greater than the second normal voltage Vd2. The second normal voltage Vd2 is the voltage of the second portion B2 when the first switch 10A and the third switch 10H are normally switched to an ON state, and the second switch 10B is normally switched to an OFF state. When the voltage value V is less than or equal to the third threshold value Th33 and greater than or equal to the fourth threshold value Th44 (Yes in step S13), the processing transitions to step S14.

When the processing transitions to step S14, the detection unit 10E performs the third switch control that maintains the first switch 10A and the third switch 10H in the OFF state, and maintains the second switch 10B in the ON state. Then, the detection unit 10E determines whether the second portion B2 has a voltage within an abnormal range. When the processing transitions to step S14, the detection unit 10E compares, in terms of magnitude, the voltage value V of the second portion B2 with the fifth threshold value Th55.

When the voltage value V is greater than the fifth threshold value Th55, it is estimated that the voltage of the second portion B2 has increased due to an open-circuit fault in the second switch 10B. Accordingly, when the detection unit 10E determines that the voltage value V is greater than the fifth threshold value Th55 (No in step S14), the processing transitions to step S16. Then, the detection unit 10E determines that the supply system 200 is in an abnormal state, and the processing shown in FIG. 5 ends. When the voltage value V is less than or equal to the fifth threshold value Th55 (Yes in step S14), the processing transitions to step S15. When the processing transitions to step S15, the detection unit 10E determines that the supply system 200 is in a normal state, and the processing shown in FIG. 5 ends. The abnormal range of the voltage of the second portion B2 in step S14 includes a voltage range that is greater than or equal to the fifth threshold value that is greater than the third normal voltage Vd3. The third normal voltage Vd3 is the voltage of the second portion B2 when the first switch 10A and the third switch 10H are normally switched to an OFF state, and the second switch 10B is normally switched to an ON state.

In the case of a configuration in which the voltage value V is compared with each threshold value using a comparator, it may be preferable to set the resistance values of the first resistor unit 10C, the second resistor unit 10D, the third resistor unit 10J, and the initiator 91C such that a value obtained by dividing the voltage at the high-potential side terminal of the power supply unit 90 by the first resistor unit 10C and the second resistor unit 10D is equal to a value obtained by dividing the voltage at the high-potential side terminal of the power supply unit 90 by the third resistor unit 10J and the initiator 91C.

The abnormality detection apparatus 110 includes a series-connection portion 10K in which the third switch 10H and the third resistor unit 10J are connected in series. One end of the series-connection portion 10K is electrically connected to the third portion B3, and another end of the series-connection portion 10K is electrically connected to the second portion B2. With this configuration, by further adding the series-connection portion 10K in which the third switch 10H and the third resistor unit 10J are connected in series, the abnormality in the supply system 200 can be more precisely determined.

In the abnormality detection apparatus 110, the detection unit 10E determines whether the second portion B2 has a voltage within an abnormal range when an OFF instruction is provided to the first switch 10A, the second switch 10B, and the third switch 10H. The abnormal range includes at least either one of a voltage range that is less than or equal to the first threshold value Th11 that is less than the first normal voltage Vd1 or a voltage range that is greater than or equal to the second threshold value Th22 that is greater than the first normal voltage Vd1. The first normal voltage Vd1 is the voltage of the second portion B2 when the first switch 10A, the second switch 10B, and the third switch 10H are normally switched to an OFF state. With this configuration, when the first switch 10A, the second switch 10B, and the third switch 10H are normally switched to an OFF state, the voltage of the second portion B2 is the first normal voltage Vd1 obtained by dividing the output voltage Vo at the high-potential side terminal of the power supply unit 90 by the first resistor unit 10C and the second resistor unit 10D. By comparing the first threshold value Th11 and the second threshold value Th22 that are based on this value as a reference with the actual voltage value V of the second portion B2, it is possible to detect a drop or an increase in the power supply voltage, a disconnection on the first power line 92 and the second power line 93, and a short-circuit failure in the first switch 10A and the second switch 10B.

In the abnormality detection apparatus 110, when an ON instruction is provided to the first switch 10A and the third switch 10H, and an OFF instruction is provided to the second switch 10B, the detection unit 10E determines whether the second portion B2 has a voltage within an abnormal range. The abnormal range includes at least either one of a voltage range that is less than or equal to the third threshold value Th33 that is less than the second normal voltage Vd2 or a voltage range that is greater than or equal to the fourth threshold value Th44 that is greater than the second normal voltage Vd2. The second normal voltage Vd2 is the voltage of the second portion B2 when the first switch 10A and the third switch 10H are normally switched to an ON state, and the second switch 10B is normally switched to an OFF state. With this configuration, when the first switch 10A and the third switch 10H are normally switched to an ON state, the second switch 10B is normally switched to an OFF state, and the initiator 91C of the pyrotechnic interrupter 91 has a normal resistance value Ri, the voltage of the second portion B2 has a value obtained by dividing the output voltage Vo at the high-potential side terminal of the power supply unit 90 by a combined resistor in which the initiator 91C and the first resistor unit 10C are connected in parallel and a combined resistor in which the second resistor unit 10D and the third resistor unit 10J are connected in parallel. By comparing the third threshold value Th33 and the fourth threshold value Th44 that are based on this value as a reference with the actual voltage value V of the second portion B2, it is possible to detect an open-circuit fault in the first switch 10A, a connection failure in the pyrotechnic interrupter 91, and a change in the resistance value Ri of the initiator 91C of the pyrotechnic interrupter 91.

In the abnormality detection apparatus 110, when an OFF instruction is provided to the first switch 10A and the third switch 10H, and an ON instruction is provided to the second switch 10B, the detection unit 10E determines whether the second portion B2 has a voltage within an abnormal range. The abnormal range includes a voltage range that is greater than or equal to the fifth threshold value Th55 that is greater than the third normal voltage Vd3 that is the voltage of the second portion B2 when the first switch 10A and the third switch 10H are normally switched to an OFF state, and the second switch 10B is normally switched to an ON state. With this configuration, when the first switch 10A and the third switch 10H are normally switched to an OFF state, and the second switch 10B is normally switched to an ON state, the voltage of the second portion B2 has a value that is equal to the voltage at the low-potential side terminal of the power supply unit 90. By comparing the fifth threshold value Th55 that is based on this value as a reference with the actual voltage value V of the second portion B2, it is possible to detect an open-circuit fault in the second switch 10B.

In the abnormality detection apparatus 110, a value obtained by dividing the output voltage Vo at the high-potential side terminal of the power supply unit 90 by the first resistor unit 10C and the second resistor unit 10D is equal to a value obtained by dividing the output voltage Vo at the high-potential side terminal of the power supply unit 90 by the third resistor unit 10J and the initiator 91C of the pyrotechnic interrupter 91. With this configuration, the first normal voltage Vd1 that is used as a reference for the first threshold value Th11 and the second threshold value Th22 can have the same value as the second normal voltage Vd2 that is used as a reference for the third threshold value Th33 and the fourth threshold value Th44. Accordingly in the case where the detection unit 10E is configured using a comparator, the number of comparators that need to be provided can be reduced.

### OTHER EMBODIMENTS

The embodiments disclosed in the specification of the present application are exemplary in all aspects, and thus should not be construed as limiting. The scope of the present disclosure is not limited to the embodiments disclosed in the specification of the present application, and all changes that come within the scope of the claims of the present application as well as the meaning and range of equivalency of the claims are intended to be embraced within the scope of the disclosure of the present application.

The order in which the first switch control, the second switch control, and the third switch control are performed may be changed from that shown in Embodiments 1 and 2.

The abnormality detection apparatus may be applied to a system that supplies an electric current to a squib in an airbag.

A configuration that is different from that of Embodiment 2 may be used in which one end of the third switch that is one end of the series-connection portion is electrically connected to the second portion, and the other end of the third resistor unit that is the other end of the series-connection portion is electrically connected to the third portion.

It is sufficient that the first resistor unit, the second resistor unit, and the third resistor unit each include a resistance element, and each of them may further include, in addition to the resistance element, a plurality of elements such as an inductor and a capacitor.

1. An abnormality detection apparatus used in a supply system including a power supply unit that supplies power, a first power line provided between a high-potential side terminal of the power supply unit and a power supply target, and a second power line provided between a low-potential side terminal of the power supply unit and the power supply target, the abnormality detection apparatus comprising:
a first switch provided on the first power line;
a second switch provided on the second power line;
a first resistor unit and a second resistor unit that form a current conduction path; and
a detection unit that detects a voltage status,
wherein, when the first switch is switched to an ON state, a current conduction via the first switch is allowed, and when the first switch is switched to an OFF state, the current conduction via the first switch is interrupted,
when the second switch is switched to an ON state, a current conduction via the second switch is allowed, and when the second switch is switched to an OFF state, the current conduction via the second switch is interrupted,
one end of the first resistor unit is electrically connected to a first portion on the first power line between the power supply unit and the first switch, and another end of the first resistor unit is electrically connected to a second portion on the second power line between the second switch and the power supply target,
one end of the second resistor unit is electrically connected to the second portion, and another end of the second resistor unit is electrically connected to a third portion on the second power line between the second switch and the power supply unit, and
the detection unit detects the voltage status of the second portion when at least either one of the first switch or the second switch is controlled to be in an OFF state.

2. The abnormality detection apparatus according to claim 1,
wherein the power supply target includes a pyrotechnic interrupter provided on a predetermined conductive path, and
the pyrotechnic interrupter includes a conductor that causes a short-circuit between a first conductive path and a second conductive path included in the predetermined conductive path, and causes an explosion to disconnect the conductor when a predetermined current flows between the first power line and the second power line.

3. The abnormality detection apparatus according to claim 1,
wherein the detection unit determines whether the second portion has a voltage within an abnormal range when an OFF instruction is provided to the first switch and the second switch, and
the abnormal range includes at least either one of a voltage range that is less than or equal to a first threshold value that is less than a first normal voltage that is the voltage of the second portion when the first switch and the second switch are normally switched to an OFF state or a voltage range that is greater than or equal to a second threshold value that is greater than the first normal voltage.

4. The abnormality detection apparatus according to claim 1,
wherein the detection unit determines whether the second portion has a voltage within an abnormal range when an ON instruction is provided to the first switch, and an OFF instruction is provided to the second switch, and
the abnormal range includes at least either one of a voltage range that is less than or equal to a third threshold value that is less than a second normal voltage that is the voltage of the second portion when the first switch is normally switched to an ON state, and the second switch is normally switched to an OFF state or a voltage range that is greater than or equal to a fourth threshold value that is greater than the second normal voltage.

5. The abnormality detection apparatus according to claim 1,
wherein the detection unit determines whether the second portion has a voltage within an abnormal range when an OFF instruction is provided to the first switch, and an ON instruction is provided to the second switch, and
the abnormal range includes a voltage range that is greater than or equal to a fifth threshold value that is greater than a third normal voltage that is the voltage of the second portion when the first switch is normally switched to an OFF state and the second switch is normally switched to an ON state.

6. The abnormality detection apparatus according to claim 1, including:
a series-connection portion in which a third switch and a third resistor unit are connected in series,
wherein one end of the series-connection portion is electrically connected to the third portion, and another end of the series-connection portion is electrically connected to the second portion.

7. The abnormality detection apparatus according to claim 6,
wherein the detection unit determines whether the second portion has a voltage within an abnormal range when an OFF instruction is provided to the first switch, the second switch, and the third switch, and
the abnormal range includes at least either one of a voltage range that is less than or equal to a first threshold value that is less than a first normal voltage that is the voltage of the second portion when the first switch, the second switch, and the third switch are normally switched to an OFF state or a voltage range that is greater than or equal to a second threshold value that is greater than the first normal voltage.

8. The abnormality detection apparatus according to claim 6,
wherein the detection unit determines whether the second portion has a voltage within an abnormal range when an ON instruction is provided to the first switch and the third switch, and an OFF instruction is provided to the second switch, and
the abnormal range includes at least either one of a voltage range that is less than or equal to a third threshold value that is less than a second normal voltage that is the voltage of the second portion when the first switch and the third switch are normally switched to an ON state and the second switch is normally switched to an OFF state or a voltage range that is greater than or equal to a fourth threshold value that is greater than the second normal voltage.

9. The abnormality detection apparatus according to claim 6,
wherein the detection unit determines whether the second portion has a voltage within an abnormal range when an OFF instruction is provided to the first switch and the third switch, and an ON instruction is provided to the second switch, and
the abnormal range includes a voltage range that is greater than or equal to a fifth threshold value that is greater than a third normal voltage that is the voltage of the second portion when the first switch and the third switch are normally switched to an OFF state, and the second switch is normally switched to an ON state.

10. The abnormality detection apparatus according to claim 6,
wherein a value obtained by dividing a voltage at the high-potential side terminal of the power supply unit by a voltage of the first resistor unit and a voltage of the second resistor unit is equal to a value obtained by dividing the voltage at the high-potential side terminal of the power supply unit by a voltage of the third resistor unit and a voltage of the power supply target.

11. The abnormality detection apparatus according to claim 2,
wherein the detection unit determines whether the second portion has a voltage within an abnormal range when an OFF instruction is provided to the first switch and the second switch, and
the abnormal range includes at least either one of a voltage range that is less than or equal to a first threshold value that is less than a first normal voltage that is the voltage of the second portion when the first switch and the second switch are normally switched to an OFF state or a voltage range that is greater than or equal to a second threshold value that is greater than the first normal voltage.

12. The abnormality detection apparatus according to claim 2,
wherein the detection unit determines whether the second portion has a voltage within an abnormal range when an ON instruction is provided to the first switch, and an OFF instruction is provided to the second switch, and
the abnormal range includes at least either one of a voltage range that is less than or equal to a third threshold value that is less than a second normal voltage that is the voltage of the second portion when the first switch is normally switched to an ON state, and the second switch is normally switched to an OFF state or a voltage range that is greater than or equal to a fourth threshold value that is greater than the second normal voltage.

13. The abnormality detection apparatus according to claim 2,
wherein the detection unit determines whether the second portion has a voltage within an abnormal range when an OFF instruction is provided to the first switch, and an ON instruction is provided to the second switch, and
the abnormal range includes a voltage range that is greater than or equal to a fifth threshold value that is greater than a third normal voltage that is the voltage of the second portion when the first switch is normally switched to an OFF state and the second switch is normally switched to an ON state.

14. The abnormality detection apparatus according to claim 2, including:
a series-connection portion in which a third switch and a third resistor unit are connected in series,
wherein one end of the series-connection portion is electrically connected to the third portion, and another end of the series-connection portion is electrically connected to the second portion.
